(19) United States
(12) Patent Application Publication
(10) Pub. No.: US 2026/0231700 A1
(43) Pub. Date: Aug. 6, 2026

(54) SURFACE TREATMENT METHOD FOR SILICON BODY AND METHOD OF MANUFACTURING SILICON STRUCTURAL BODY

(71) Applicants: TAKANO CO., LTD., Nagano (JP); NAGANO Prefecture, Nagano (JP)

(72) Inventors: Akira SATO, Nagano (JP); Hideaki MIZUSAKI, Nagano (JP)

(21) Appl. No.: 19/149,853

(22) PCT Filed: Dec. 19, 2023
(86) PCT No.: PCT/JP2023/045568

§ 371 Date: Jul. 22, 2025

(30) Foreign Application Priority Data
Jan. 25, 2023 (JP) 2023-009360

(51) Int. Cl. H10P 14/40; H10P 14/47

(52) U.S. Cl. CPC H10P 14/414; H10P 14/418; H10P 14/48

(57) ABSTRACT

A surface treatment method for a silicon body of a silicon structural body according to the present invention includes: a silicide layer forming step of forming a silicide layer by siliciding a surface of the silicon body; and a plating layer forming step of forming a plating layer on the silicide layer. Further, a manufacturing method of a silicon structural body according to the present invention includes: a silicide layer forming step of forming a silicide layer by siliciding a surface of a silicon body; and a plating layer forming step of forming a plating layer on the silicide layer. The present invention provides the surface treatment method for a silicon body of a silicon structural body and a manufacturing method of a silicon structural body that can enhance a mechanical property of a silicon structural body.

### RELATED APPLICATIONS

The present application is a National Phase of International Application No. PCT/JP2023/045568 filed Dec. 19, 2023, which claims priority to Japanese Application No. 2023-009360, filed Jan. 25, 2023.

### TECHNICAL FIELD

The present invention relates to a surface treatment method for a silicon body and a method of manufacturing a silicon structural body.

### BACKGROUND ART

The development of micro electro mechanical systems (MEMS) constructed by integrating mechanical element parts, sensors, actuators, electronic circuits and the like on a silicon board or a glass board has been in progress. As an example of the MEMS, a mechanical oscillator that is operated in an electron microscope that forms a minute space under a high vacuum can be named (see patent literature 1).

Patent literature 1, as illustrated in FIG. 9, discloses the invention relating to a mechanical oscillator 900 that includes: a base portion 901 formed of a support substrate such as an SOI substrate; and a structural body 902 that forms a cantilever that is formed of a silicon thin film of the SOI substrate, and protrudes horizontally from the base portion 901. In the mechanical oscillator 900, a part of an embedded oxide film 903 disposed between the base portion 901 and the structural body 902 that forms a cantilever is removed. Further, the structural body 902 that forms a cantilever is directly bonded to a distal end 905 of the base portion 901 from which the embedded oxide film 903 is removed, thus forming the mechanical oscillator 900 provided with the cantilever 904 that uses the distal end 905 of the base portion 901 as an initiation point.

### PRIOR ART LITERATURE

### Patent Literature

Patent Literature

[Patent literature 1] International publication WO2006/062048

### SUMMARY OF INVENTION

### Technical Problem

However, in a case where the silicon thin film of the SOI substrate forms a movable portion like the silicon structural body (mechanical oscillator 900) described in patent literature 1, there exists a problem that a fracture strength of the silicon structural body is not sufficient. To be more specific, in a process of manufacturing a silicon structural body, the structural body having a particular shape is formed by an etching process, and there is a case where a crystal structure of silicon that forms the silicon structural body is damaged in an etching process. Accordingly, a fracture strength of the silicon structural body against bending and twisting is lowered.

The problem that a fracture strength is not sufficient is a problem relating to the manufacture process. Accordingly, even in a case where a silicon structural body is not manufactured from an SOI substrate, there is a concern that substantially the same problem arises. As a result that a fracture strength of the silicon structural body is not sufficient, there has been a case where, when a large strength is applied to a silicon structural body that is a product or when the silicon structural body is used beyond a predetermined period, the silicon structural body is fractured.

In view of the above-mentioned circumstances, it is an object of the present invention to provide a surface treatment method for a silicon body of a silicon structural body that enhances a mechanical property, particularly, a fracture strength of a silicon body. It is another object of the present invention to provide a method of manufacturing a silicon structural body that enhances a mechanical property, particularly, a fracture strength of a silicon body.

### Solution to Problem

[1] A surface treatment method for a silicon body according to the present invention is a surface treatment method for a silicon body of a silicon structural body that includes: a silicide layer forming step of forming a silicide layer by siliciding a surface of the silicon body; and
a plating layer forming step of forming a plating layer on the silicide layer.

[2] In the surface treatment method for a silicon body of a silicon structural body according to the present invention, it is preferred that the plating layer forming step is a step of forming the plating layer on the silicide layer in a self-aligning manner.

[3] In the surface treatment method for a silicon body of a silicon structural body according to the present invention, it is preferred that the plating layer forming step is a step of forming the plating layer by electroless plating or electrolytic plating.

[4] In the surface treatment method for a silicon body of a silicon structural body according to the present invention, it is preferred that the plating layer forming step is a step of forming a plating layer that contains one, two or more metals selected from nickel, copper, gold, silver, zinc, tin and chromium.

[5] In the surface treatment method for a silicon body of a silicon structural body according to the present invention, it is preferred that the silicide layer forming step includes: a step of forming a thin film that contains one, two or more materials selected from a silicon oxide and an inorganic compound that obstruct formation of the silicide layer for forming a region of a surface of the silicon body where the silicide layer is not formed; and a step of forming a metal layer in a region of a surface of the silicon body where the thin film is not formed.

[6] In the surface treatment method for a silicon body of a silicon structural body according to the present invention, it is preferred that the silicon body is a silicon thin film formed over a support substrate.

[7] In the surface treatment method for a silicon body of a silicon structural body according to the present invention, it is preferred that the silicon body is a single-crystal silicon body or a poly-crystal silicon body.

[8] A manufacturing method of a silicon structural body according to the present invention includes: a silicide layer forming step of forming a silicide layer by siliciding a surface of a silicon body; and a plating layer forming step of forming a plating layer on the silicide layer.

### Advantageous Effects of Invention

The surface treatment method for a silicon body of a silicon structural body according to the present invention, and the method of manufacturing a silicon structural body according to the present invention include: the silicide layer forming step of forming the silicide layer; and the plating layer forming step of forming the plating layer on the silicide layer. With such steps, it is possible to make plating precipitate on the surface of the silicon body made of a difficult-to-plate material. Further, the plating layer formed on the surface of the silicon body can enhance a mechanical property, particularly, a bending resistance and a torsional resistance of the silicon body.

That is, according to one aspect of the present invention, it is possible to provide the surface treatment method for a silicon body of a structural body that enables applying of plating to the surface of the silicon body and, at the same time, can enhance a mechanical property of the silicon body.

Further, according to another aspect of the present invention, it is possible to provide the manufacturing method of a silicon structural body that enables the precipitation of the plating on the surface of the silicon body and, at the same time, can enhance a mechanical property of the silicon body.

### BRIEF DESCRIPTION OF DRAWINGS

FIG. 1 is a flowchart illustrating a surface treatment method for a silicon body of a silicon structural body according to an embodiment 1.

FIG. 2A to FIG. 2E are views illustrating the surface treatment method for a silicon body of a silicon structural body according to the embodiment 1.

FIG. 3 is a flowchart illustrating a silicon prism 20 of the silicon structural body according to an embodiment 2.

FIG. 4A to FIG. 4D are views illustrating a manufacturing method of the silicon prism 20 according to the embodiment 2.

FIG. 5A and FIG. 5B are views illustrating the buckling resistance evaluation of a silicon prism 20 according the embodiment 2. FIG. 5A is a graph illustrating an evaluation result of a buckling resistance of the silicon prism 20 according to the embodiment 2, and FIG. 5B is a view illustrating an evaluation method of buckling resistance of the silicon prism 20.

FIG. 6 is a flowchart illustrating a manufacturing method of a cantilever 30 that is a silicon structural body according to an embodiment 3.

FIG. 7A to FIG. 7E are views illustrating a manufacturing method of the cantilever 30 according to the embodiment 3.

FIG. 8A to FIG. 8E are views illustrating a manufacturing method of an MEM mirror 40 that is a silicon structural body according to an embodiment 4.

FIG. 9 is a view illustrating a mechanical oscillator 900 according to a prior art.

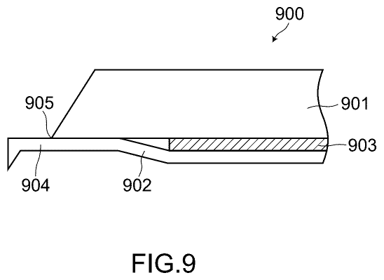

### DESCRIPTION OF EMBODIMENTS

Hereinafter, a surface treatment method for a silicon body of a silicon structural body and a method of manufacturing a silicon structural body according to the present invention are described. The embodiment described hereinafter does not intend to limit the present invention called for in claims. Further, it is not always the case that all of various elements described in the embodiment and the combinations of these elements are indispensable in the present invention.

### Embodiment

### 1. Surface Treatment Method for a Silicon Body of a Silicon Structural Body (Embodiment 1)

### 1-1. Overall Configuration

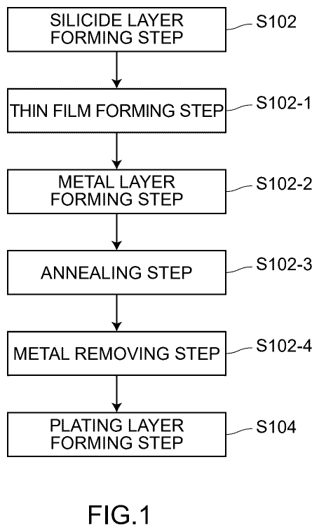

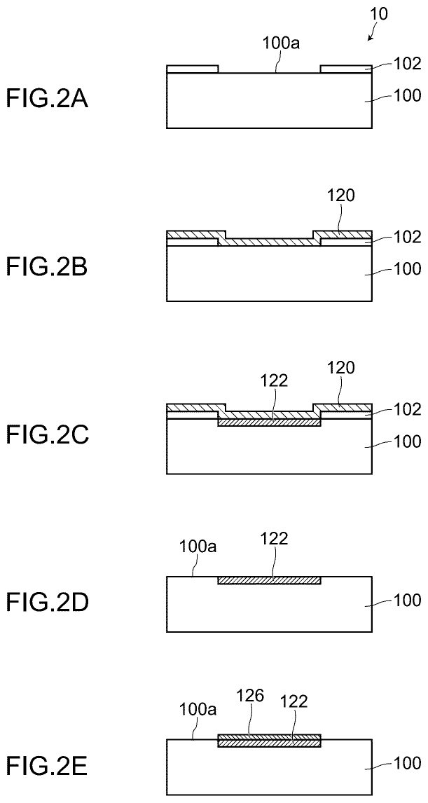

FIG. 1 is a flowchart illustrating a surface treatment method for a silicon body of a silicon structural body according to an embodiment 1. FIG. 2A to FIG. 2E are views illustrating the surface treatment method for a silicon body of a silicon structural body according to the embodiment 1.

First, the silicon body that is a target of surface treatment in the surface treatment method for a silicon body according to the embodiment 1 is described. In the silicon body used in the embodiment 1, a kind, the shape and a size of of silicon crystals that form the silicon body are not limited provided that the silicon body constitutes a part of the entirety of the silicon structural body.

As the kind of silicon crystals, a single-crystal silicon, a poly-crystal silicon, a non-crystal (amorphous) silicon can be preferably used. Among these kinds of silicon, it is more preferable to use a single-crystal silicon or a poly-crystal silicon as silicon for forming the silicon body. By using a single-crystal silicon or a poly-crystal silicon as silicon for forming the silicon body, the silicon structural body that exhibits an excellent mechanical strength can be manufactured.

Further, with respect to the shape of the silicon body, the silicon body may be formed in a block shape instead of a thin-film shape. Particularly, it is preferred that the silicon body is a silicon thin film formed over the support substrate, or a silicon thin film formed via a sacrifice layer formed over a support substrate.

Hereinafter, with reference to FIG. 1 and FIG. 2A to FIG. 2E, the surface treatment method for a silicon body of a silicon structural body is described. In the description made hereinafter, for the sake of convenience of the explanation, as an example, the description is made with respect to a case where a silicide layer 122 is formed on a portion of a surface 100a of the silicon substrate 100 (hereinafter “a surface 100a of the silicon substrate 100” being also simply referred to as “surface 100a” in some cases), and a plating layer 126 is formed on the silicide layer 122.

As illustrated in FIG. 1, the surface treatment method for the silicon body of the silicon structural body 10 according to the embodiment 1 includes: a silicide layer forming step S102; and a plating layer forming step S104.

### 1-2 Silicide Layer Forming Step

The silicide layer forming step S102 is a step where a surface 100a is silicided thus forming the silicide layer 122 on the surface 100a (see FIG. 2A to FIG. 2D).

The silicide layer forming step S102 includes a metal layer forming step S102-2 and an annealing step S102-3. The silicide layer forming step S102 may also include: a step S102-1 where a thin film 102 that obstructs the formation of the silicide layer on a portion of the surface 100a is formed; and a metal removing step S102-4.

The step S102-1 for forming the thin film 102 that obstructs the formation of the silicide layer (hereinafter, also referred to as “thin film forming step S102-1” in some cases) is a step where the thin film 102 that obstructs the formation of the silicide layer 122 is formed in a region where the formation of the silicide layer 122 on the surface 100a is unnecessary.

In the above treatment, the thin film 102 that obstructs the formation of the silicide layer (hereinafter, simply referred to as “thin film 102”) is the thin film 102 that obstructs the formation of the silicide layer on the surface 100a when the thin film 102 is formed on the surface 100a, and a metal layer 120 that contains metal that forms silicide together with silicon is formed on the thin film 102 and heat treatment is performed. To be more specific, a thin film that contains one or more substances selected from silicon oxide and an inorganic compound can be exemplified.

By forming the thin film 102 in the region of the surface 100a where the formation of the silicide layer 122 is unnecessary, the silicide layer 122 can be selectively formed in the region where the formation of the silicide layer 122 on the surface 100a is necessary. In a case where an entire region of the surface 100a is silicided, it is unnecessary to form the thin film 102 on the surface 100a.

A metal layer forming step S102-2 is a step where the metal layer 120 is formed on the surface 100a (see FIG. 2B). The formation of the metal layer 120 on the surface 100a can be performed by a known method such as a sputtering method.

With respect to metal used in the metal layer 120, any metal can be used without being particularly restricted provided that metal forms silicide together with silicon. As metals that can be used in the metal layer 120, molybdenum, titanium, copper, cobalt, chromium, nickel, platinum or the like can be exemplified.

The region where the metal layer 120 is formed is a region where at least the silicide layer 122 is formed on the surface 100a. In the above-mentioned thin film forming step S102-1, in a case where the thin film 102 is formed in the region of the surface 100a where the formation of the silicide layer 122 is not necessary, the metal layer 120 may be formed in both of the region where the silicide layer 122 is formed and the region where the thin film 102 is formed.

The annealing step S102-3 is a step where heat treatment is applied to the silicon substrate 100 on which the metal layer 120 is formed, and a region of the surface 100a is formed into silicide thus forming the silicide layer 122 (see FIG. 2C). The heat treatment condition in the annealing step S102-3 can be suitably decided by taking into account a kind of metal contained in the metal layer 120 and a melting point of silicon. As one example of the heat treatment, the heat treatment is performed within a temperature range of 100° C. to 700° C.

In the annealing step S102-3, the surface 100a that is in contact with the metal layer 120 is formed into silicide so that the silicide layer 122 is formed on the surface 100a. In a portion of the surface 100a where the metal layer 120 is formed via the thin film 102, the formation of the silicide layer 122 is obstructed by the thin film 102 and hence, the surface 100a is not formed into silicide so that the silicide layer 122 is not formed.

The metal removing step S102-4 is a step of removing metal that is not silicided at the time of performing siliciding and remains on an upper surface of the silicide layer 122 by etching. In etching, a non-reacted metal is removed from an upper surface of the silicide layer 122 by wet etching that uses a mixed acid, a hydrogen peroxide-based acid or the like. Further, by removing the thin film 102, it is possible to obtain a silicon substrate 100 where the silicide layer 122 is formed on the surface 100a in a predetermined region (see FIG. 2D).

### 1-3. Plating Layer Forming Step

The plating layer forming step S104 is a step of forming a plating layer 126 on the surface of the silicide layer 122 (see FIG. 2E). A material used in plating is not particularly restricted provided that the material can form the plating layer 126 on the surface of the silicide layer 122. As a material that can be used for plating, metal such as nickel, copper, gold, silver, zinc, tin or chromium or the like, or, two or more metals selected from these metals can be used.

With respect to the method of forming the plating layer 126 on the surface of the silicide layer 122, the method is not particularly restricted provided that the method can form the plating layer 126 on the silicide layer 122.

As the method of forming the plating layer 126, electroless plating or electrolytic plating can be preferably used.

Electroless plating and electrolytic plating are excellent with respect to a point that these plating can uniformly precipitate various kinds of metals on the surface of the silicide layer 122. Further, the plating layer 126 having a large film thickness can be formed on the surface of the silicide layer 122. That is, by forming the plating layer 126 by electroless plating or electrolytic plating, it is possible to form the plating layer 126 having a large thickness and a uniform film thickness.

The plating layer 126 is formed on the silicide layer 122 in a self-aligning manner. That is, in the plating layer forming step S104, a plating material selectively precipitates only on a surface of the silicide layer 122, and there is no concern that a plating material precipitates on the surface 100a where the silicide layer 122 is not formed.

The surface treatment method for a silicon body according to the embodiment 1 includes the silicide layer 122 forming step S102 of forming the silicide layer 122 by siliciding the surface 100a of the silicon surface forming layer. With such treatment, it is possible to precipitate plating on the surface 100a of the surface forming layer made of silicon that is a material whose plating is difficult.

By covering the surface 100a with the plating layer 126, it is possible to suppress a fracture of the silicon structural body 10 caused by disturbance of silicon crystals. To be more specific, it is possible to suppress the fracture of the silicon structural body 10 when a force that bends the silicon structural body 10 is applied to the silicon structural body 10. Further, it is possible to enhance torsional resistance when a force in a twisting direction is applied to the silicon structural body 10.

Further, in the plating layer forming step S104, with respect to the plating layer 126, the plating layer 126 is selectively formed only in the region where the silicide layer 122 is formed. That is, the plating layer 126 is formed on the surface of the silicide layer 122 in a self-aligning manner.

That is, by selectively forming the plating layer in the region where the silicide layer 122 is formed, a mechanic characteristic can be enhanced and, at the same time, an electrical conductivity can be secured. On the other hand, in the region where the silicide layer 122 is not formed, the plating layer 126 is not formed. Accordingly, it is possible to prepare a device that makes use of a characteristic that the surface 100a originally possesses, for example, a reflection characteristic based on a flat smooth surface.

### 2. Method of Manufacturing Silicon Structural Body (Embodiment 2)

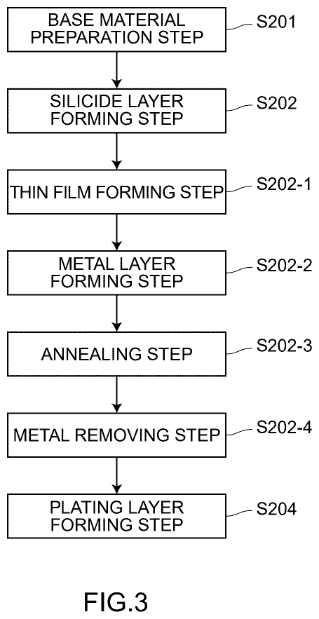

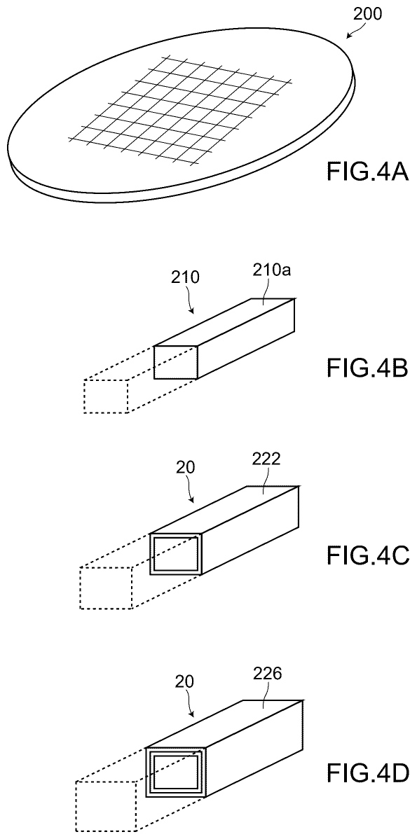

FIG. 3 is a flowchart illustrating a manufacturing method of the silicon prism 20 that is a silicon structural body according to the embodiment 2. FIG. 4A to FIG. 4D are views illustrating the manufacturing method of the silicon prism 20 according to the embodiment 2. FIG. 4B to FIG. 4D are views illustrating a manufacture intermediate body of the silicon prism 20. However, to describe the cross-sectional structure, a portion of the silicon prism 20 is indicated by a dotted line.

Hereinafter, the manufacturing method of the silicon prism 20 is described with reference to FIG. 3 and FIG. 4A to FIG. 4D. The method of manufacturing the silicon prism 20 according to the embodiment 2 includes a surface treatment method for a silicon body of the silicon prism 20. Further, in a case where the description of the constitutional elements of the embodiment 1 and the constitutional elements of the embodiment 2 overlap with each other, the description of the constitutional elements may be omitted when appropriate.

As illustrated in FIG. 3, the manufacturing method of the silicon prism 20 according to the embodiment 2 includes a base material preparation step S201, a silicide layer forming step S202, and a plating layer forming step S204.

### 2-1. Base Material Preparation Step

The base material preparation step S201 is a step of preparing a base material that becomes a material of the silicon prism 20. In the base material preparation step S201, a silicon substrate 200 that becomes the base material is prepared, the silicon substrate 200 is polished or etched until the silicon substrate 200 has a predetermined thickness thus adjusting a thickness of the silicon substrate 200. A thickness of the silicon substrate 200 after performing polishing or the like is, for example, 0.1 mm (100 μm). The thickness of the silicon substrate 200 after polishing is provided as an exemplifying purpose, and the silicon substrate 200 is not limited to such a thickness.

The silicon substrate 200 whose thickness is adjusted to the predetermined thickness is cut into a predetermined size by performing dicing. For example, the silicon substrate 200 is cut into pieces each having a width of 0.1 mm (100 μm) and a length of 30 mm thus obtaining the prism-shaped base material 210 having a length of 100 μm (longitudinal direction), a width of 100 μm (lateral direction) and a height of 30 mm (vertical direction) (see FIG. 4B). The above-mentioned sizes of the base material 210 are provided only for an exemplifying purpose, and the base material 210 is not limited to such sizes.

### 2-2. Silicide Layer Forming Step

The silicide layer forming step S202 is a step of forming a silicide layer 222 on a surface 210a by siliciding the surface 210a of a silicon body of the base material 210 (hereinafter, “the surface 210a of a silicon body of the base material 210” also being simply referred to as “the surface 210a”. That is, the silicide layer 222 is formed on the surface 210a of the base material 210 having a prism shape cut out from the silicon substrate 200 (see FIG. 4C).

The silicide layer forming step S202 is the same as the silicide layer forming step S102 in the surface treatment method for a silicon body according to the embodiment 1 and hence, the description of the silicide layer forming step S202 is omitted.

### 2-3. Plating Layer Forming Step

The plating layer forming step S204 is a step of forming a plating layer 226 on the surface of the silicide layer 222. That is, the plating layer 266 is formed on a surface of a silicide layer 222 formed on the surface 210a (see FIG. 4D).

The silicide layer forming step S204 is the same as the silicide layer forming step S104 in the surface treatment method for a silicon body according to the embodiment 1 and hence, the description of the silicide layer forming step S204 is omitted.

A buckling resistance that is one of mechanical strengths is evaluated with respect to the silicon prism 20 obtained by performing the steps described above.

A silicon prism 20 manufactured from a commercially available single-crystal silicon wafer and having a length of 100 μm, a width of 100 μm, and a height of 30 mm was used as an evaluation-use sample. First, one surface of the commercially available silicon wafer was polished until a thickness of the substrate became 0.1 mm (100 μm). Then, the substrate having the thickness of 0.1 mm was diced thus obtaining the prism-like base material 210 having a length of 0.1 mm, a width of 0.1 mm and a height of 30 mm.

The silicide layer 222 is formed on a surface of the base material 210 and, further, nickel plating 226 is formed on the silicide layer 222 thus preparing a silicon prism 20 for evaluation. In the steps, conditions for forming the silicide layer 222 and conditions for forming the plating layer 226 are as follows.
Conditions for forming silicide layer 222
metal layer: nickel, 30 nm
heat treatment condition: 300° C., 5 min
Conditions for forming plating layer 226
plating method: electroless plating
plating layer: nickel, 0.1 um

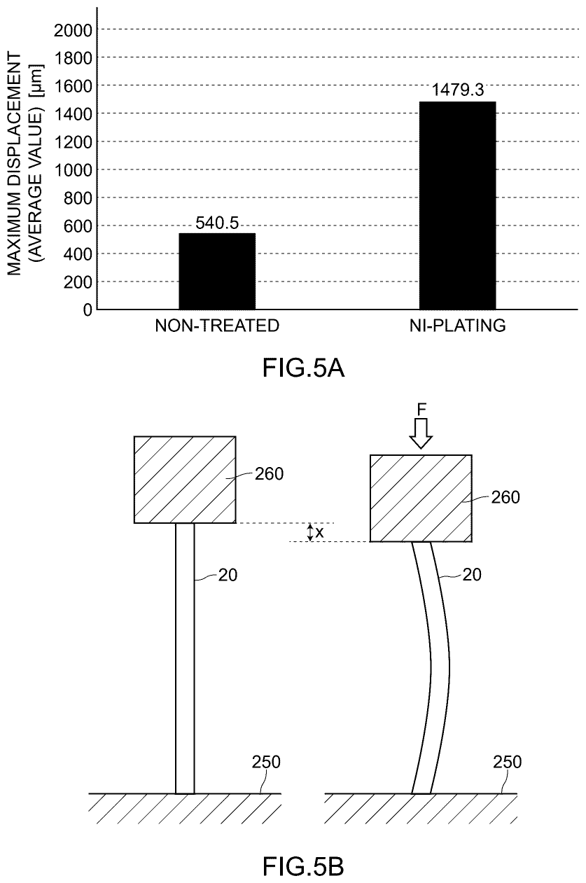

FIG. 5A and FIG. 5B are views illustrating the buckling resistance evaluation of the silicon prism 20 according the embodiment 2. FIG. 5A is a graph illustrating an evaluation result of buckling resistance of the silicon prism 20 according to the embodiment 2, and FIG. 5B is a view illustrating an evaluation method of buckling resistance of the silicon prism 20.

A buckling resistance test of the silicon prism 20 was performed in accordance with a method described below. As illustrated in FIG. 5B, the silicon prism 20 was mounted vertically on a horizontal platform 250, and the silicon prism 20 is pressed downward vertically using a jig 260. The silicon prism 20 is continuously pressed even when the silicon prism 20 is deflected, and a displacement amount x when the silicon prism 20 fractured was measured as a maximum displacement amount.

Three samples “Ni plated” that are samples where the surface 210a was silicided and the plating layer 226 was formed on the silicided surface 210a were prepared, and three samples “non-treated” that are samples where the plating layer 226 was not formed on the surface 210a were prepared. Data was collected on each of three samples “Ni plated” and an average value was set as a measurement result. In the same manner, data was collected on each of three samples “non-treated” and an average value was set as a measurement result.

The evaluation result was illustrated in FIG. 5A. The maximum displacement of the “non-treated” silicon prism 20 was 540.5 μm. On the other hand, the maximum displacement of the “Ni-plated” sample having the surface 210a on which the nickel plating layer 226 was formed was 1479.3 μm. From the evaluation result, it was found that, with respect to the maximum displacement amount of the silicon prism 20 when the silicon prism 20 was buckled, the silicon prism 20 having the plating layer 226 on the surface 210a exhibited the maximum displacement amount approximately 2.7 times larger than the maximum displacement amount of the silicon prism 20 having no plating layer 226 on the surface 210a. Accordingly, it is safe to say that a mechanical property, particularly, a bending resistance is remarkably enhanced by forming the plating layer 226 on the surface 210a.

The above-mentioned result proves that it is possible to prevent the silicon prism 20 from being fractured by suppressing damages that the silicon prism 20 received during manufacturing such as etching or dicing by protecting the silicon prism 20 with the plating layer 226.

### 3. Embodiment 3

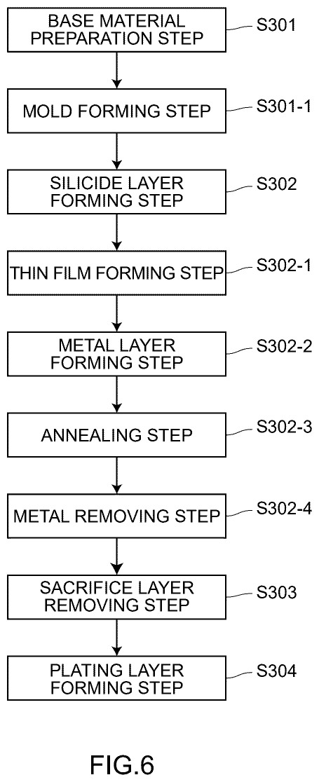

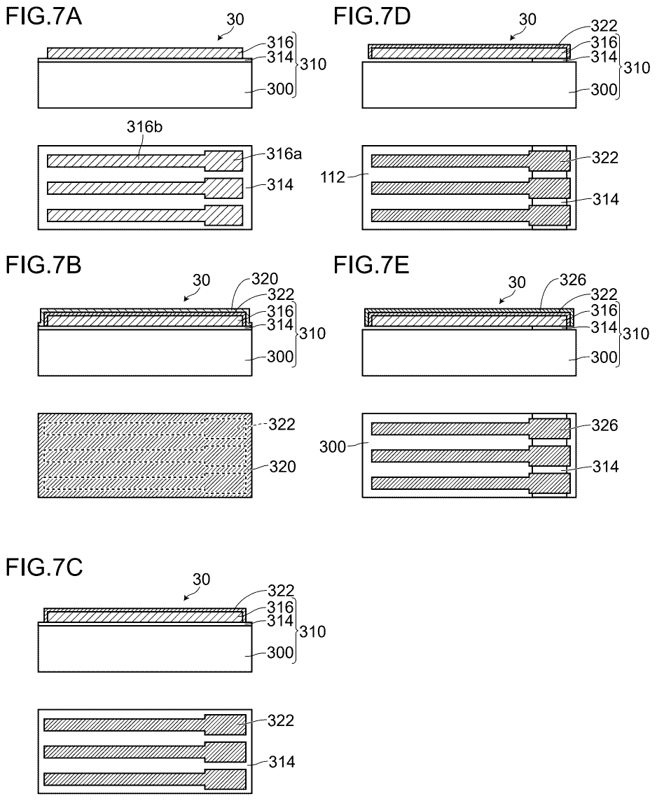

FIG. 6 is a flowchart illustrating a manufacturing method of a cantilever 30 that is a silicon structural body according to the embodiment 3. FIG. 7A to FIG. 7E are views illustrating a manufacturing method of a cantilever 30 according to the embodiment 3. In the respective views in FIG. 7A to FIG. 7E, views on an upper side are front views of the cantilever 30 in the midst of the manufacture of the silicon structural body and the completed cantilever 30, and views on a lower side are top plan views of the cantilever 30 in the midst of the manufacture of the silicon structural body and the completed cantilever 30,

Hereinafter, the manufacturing method of the cantilever 30 is described with reference to FIG. 6 and FIG. 7A to FIG. 7E. The manufacturing method of the cantilever 30 according to the embodiment 3 includes a surface treatment method for a silicon body in the cantilever 30. Further, in a case where the description of the embodiment 3 overlaps with the descriptions of the embodiments 1 and 2 in preparing the description of embodiment 3, there may be a case where the description of the overlapping portion of the embodiment 3 is omitted.

### 3-1. Base Material Preparation Step

In the base material preparation step S301, an SOI substrate 310 is prepared. As illustrated in FIG. 7A, the SOI substrate 310 is a substrate having the structure where an embedded oxide film is inserted between a silicon substrate 300 and a silicon thin film 316. The embedded oxide film interposed between the silicon substrate 300 and the silicon thin film 316 is used for the purpose of separating the silicon substrate 300 and the silicon thin film 316 from each other, and is a film having high selectivity in etching. Accordingly, the embedded oxide film is referred to as a sacrifice layer 314 hereinafter.

The sacrifice layer 314 is not limited to an oxide film. Provided that the sacrifice layer 314 can be selectively removed by a means such as etching in the manufacture of the cantilever 30 that is a silicon structural body, a kind of a material that forms the sacrifice layer 314 is not restricted. As a material for forming the sacrifice layer 314, besides a silicon oxide film, a silicon insulation film, a resist, ceramic and the like can be named.

In a case where the SOI substrate 310 is used as the base material, by removing a portion of the sacrifice layer 314, it is possible to make the silicon thin film 316 spaced apart from the silicon substrate 300. Accordingly, as described later, a beam portion of the cantilever 30 is separated from the silicon substrate 300 thus making the beam portion function as a cantilever 30.

As a kind of silicon that can be used for forming the silicon thin film 316, a single-crystal silicon, a poly-crystal silicon, a non-crystal (amorphous) silicon can be exemplified. Among these kinds of silicon, a single-crystal silicon or poly-crystal silicon can be preferably used. By forming the silicon thin film 316 using single-crystal silicon or poly-crystal silicon, it is possible to manufacture the cantilever 30 having an excellent mechanic strength.

The mold forming step S301-1 is a step where the shape of a structural body is formed on a silicon thin film 316. To be more specific, photolithography and etching are applied to the silicon thin film 316 thus forming the structural body on the silicon thin film 316 (see FIG. 7A). Although dry etching and wet etching can be named as an etching method, dry etching is preferred from a viewpoint that the structural body can be formed into an extremely fine shape.

In FIG. 7A, three structural bodies that are scheduled to become cantilevers 30 later are formed on the sacrifice layer 314. Each structural body includes: a support portion 316a that is scheduled to be a support portion of the cantilever 30 later; and a beam portion 316b that is scheduled to be a beam of the cantilever 30 later.

### 3-2. Silicide Layer Forming Step

The silicide layer forming step S302 includes a metal layer forming step S302-2 and an annealing step S302-3.

The metal layer forming step S302-2 is a step where the metal layer 320 is formed on the silicon thin film 316 and the exposed sacrifice layer 314. Any arbitrary metal can be selected as metal contained in the metal layer 330 provided that the metal forms silicide together with silicon that constitutes the silicon thin film 316.

In a case where metal having a small diffusion coefficient to silicon is selected, there is no concern that silicidation reaches a bottom surface of the structural body in the annealing step 302-3 and hence, there is no concern that the bottom surface of the structural body is plated in the plating layer forming step.

On the other hand, in a case where metal having a large diffusion coefficient to silicon is selected, for example, copper, gold or the like is selected, the entire structural body is silicided. An etching damage that is caused at the time of forming the structural body is large on side surfaces of the structural body. However, by selecting metal having a large diffusion coefficient as metal for forming the metal layer 320, the silicide layer 322 can be formed over the entire structural body in the thickness direction. As a result, in the plating layer forming step S304 described later, the plating layer 326 can be formed also on the side surfaces of the structural body and hence, a damage caused by etching on the side surfaces of the active structural body can be repaired. Accordingly, a fracture resistance of the structural body can be enhanced and, at the same time, the reduction of resistance of a probe can be also realized.

In the annealing step S302-3, as illustrated in FIG. 7B, annealing is applied to a surface of the silicon thin film 316 on which the metal layer 320 is formed and hence, the entirety or a portion of a surface of the silicon thin film 316 is silicided whereby the silicide layer 322 is formed. An annealing temperature can be suitably decided by taking into account kinds of metals contained in the metal layer 320 and a melting point of silicon. As an example, a temperature range of from 100° C. to 70° C. can be named.

In the annealing step S302-3, only the silicon thin film 316 is selectively silicided so that the silicide layer 322 is formed only on the surface of the silicon thin film 316. The surface of the sacrifice layer 314 is not silicided (see FIG. 6(b)).

The metal removing step S302-4 is a step of removing metal that is not silicided at the time of performing siliciding and remains on the silicide layer 322 by etching (see FIG. 6(c)). Etching is performed by wet etching using an etchant that is prepared by mixing a hydrochloric acid, a sulfuric acid, hydrogen peroxide and the like.

### 3-3: Sacrifice Layer Forming Step

In the sacrifice layer forming step S303, with respect to the sacrifice layer 314, the sacrifice layer 314 that exists at a lower layer of the support portion 316a is left and the sacrifice layer 314 at other places is removed. By removing the sacrifice layer 314, in the structural body, only the beam portions 316b are spaced apart from the silicon substrate 300. By performing such a step, the forming of the structure of the cantilever 30 is completed.

### 3-4: Plating Layer Forming Step

The plating layer forming step S304 is, as illustrated in FIG. 6 (e), a step where a plating layer 326 is formed on the surface of the silicide layer 322. As a material that can be used in plating, metal such as nickel, copper, gold, silver, zinc, tin, chromium or the like, or two or more metals selected from the above-mentioned metals can be exemplified.

In the manufacturing method of the silicon structural body of the present invention, a layer made of metal (plating layer 326) is formed on the surface of the silicide layer 322 by forming the plating layer 326. In a case where the silicon structural body has a stereoscopic shape such as the cantilever 30 according to the embodiment 3, it is difficult to form the metal layer having the same thickness on the upper surface and the side surfaces of the beam portion 316b of the cantilever 30 by sputtering or vapor deposition. On the other hand, according to the manufacturing method of the cantilever according to the embodiment 3 where the plating layer 326 is formed by plating, the plating layer 326 having the same thickness as the plating layer formed on the upper surface of the cantilever can be formed also on the side surfaces of the beam portions 316b of the cantilever 30.

The manufacturing method of the cantilever 30 according to the embodiment 3 described above includes the silicide layer forming step S302 where the silicide layer 322 is formed by siliciding the surface of the silicon thin film 316. With such treatment, it is possible to precipitate plating on the surface of the silicon thin film 316 that is made of a difficult-to-plate material. Further, by forming the plating layer 326 on the surface of the silicon thin film 316, it is possible to provide a surface treatment method of a silicon body and the manufacturing method of the cantilever 30 that enhance a mechanical property, to be more specific, a bending characteristic of the silicon body.

That is, according to one aspect of the present invention, it is possible to facilitate the precipitation of plating by siliciding the surface of the silicon body. In other words, it is possible to provide the surface treatment method for the silicon body that facilitates the formation of the plating layer 326 on the silicon body and, at the same time, to enhance a mechanical property of the silicon body.

Further, the embodiment 3 can also acquire an advantageous effect that the electrical conductivity can be secured by forming the plating layer 326 on the silicide layer 318.

### 4. Embodiment 4

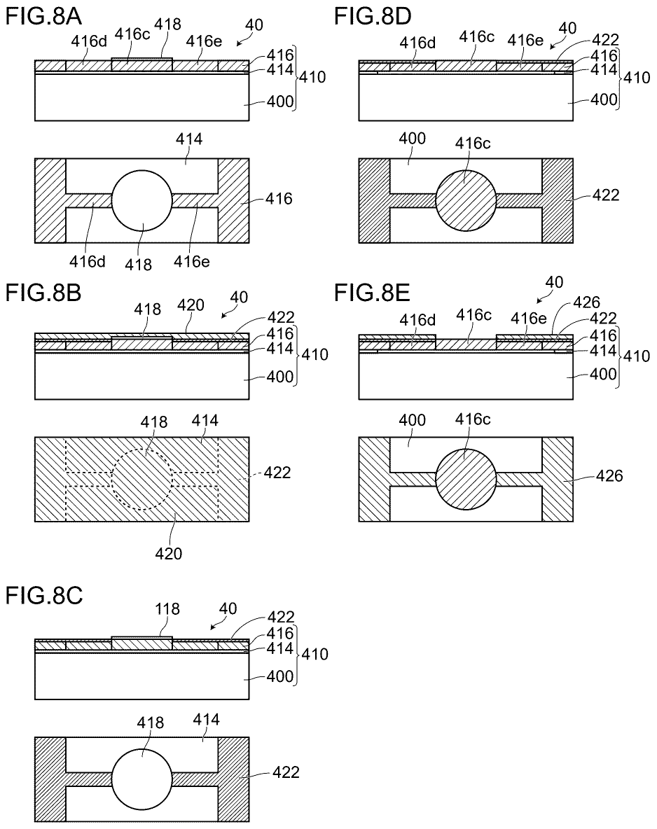

FIG. 8A to FIG. 8E are views illustrating a manufacturing method of an MEMS mirror 40 that is a silicon structural body according to the embodiment 4. In the respective views illustrated in FIG. 8A to FIG. 8E, views disposed on an upper side are front views of the MEMS mirror 40 in the course of manufacturing or completed MEMS mirror 40 as viewed from a front side, and views disposed on a lower side are top plan views of the MEMS mirror 40 in the course of manufacturing or completed MEMS mirror 40 as viewed from an upper side. Further, a flowchart illustrating the manufacturing method of the MEMS mirror 40 is the same as the flowchart illustrating the manufacturing method of the cantilever 30 according to the embodiment 3 and hence, the manufacturing method of the MEMS mirror 40 is described using FIG. 6.

Hereinafter, the manufacturing method of the MEMS mirror 40 is described with reference to FIG. 6 and FIG. 8A to FIG. 8E. The manufacturing method of the MEMS mirror 40 according to the embodiment 4 includes a surface treatment method of a silicon body in the MEMS mirror 40. Further, in a case where the description of the embodiment 4 overlaps with the descriptions of the embodiments 1 to 3 in providing the description of embodiment 4, there may be a case where the description of the overlapping portion of the embodiment 4 is omitted.

### 4-1. Base Material Preparation Step

In the base material preparation step S301, an SOI substrate 410 is prepared. Next, in a mold forming step S301-1, as illustrated in FIG. 8A, photolithography and etching are applied to a silicon thin film 416 of the SOI substrate 410 thus forming a structural body on the silicon thin film 416 of the SOI substrate 410. The structural body includes: a mirror portion 416c disposed at a center portion thereof; a beam portion 416d that extends toward a left side in the drawing; and a beam portion 416e that extends toward a right side in the drawing. Further, on a surface of the mirror portion 416c, a thin film, for example, an oxide film 418 is formed. The thin film is provided for preventing metal from adhering to a surface of the silicon thin film 416 and for maintaining flatness of the surface of the silicon thin film 416 during a period that the MEMS mirror 40 is manufactured.

### 4-2. Silicide Layer Forming Step

The silicide layer forming step S302 includes a metal layer forming step S302-2, and an annealing step S302-3.

The metal layer forming step S302-2 is a step where a metal layer 420 is formed on the silicon thin film 416 and an exposed sacrifice layer 414. The metal layer 420 may be also formed on an oxide film 418. Any arbitrary metal can be selected as metal contained in the metal layer 420 provided that the metal can form silicide together with silicon that constitutes the silicon thin film 416.

An annealing step S302-3 is a step where annealing is applied to a surface of the silicon thin film 416 on which at least the metal layer 420 is formed and hence, the entirety or a portion of a surface of the silicon thin film 416 is silicided whereby a silicide layer 422 is formed (see FIG. 8B.

In the annealing step S302-3, only the silicon thin film 416 is selectively silicided and hence, the silicide layer 422 is formed on a surface of the silicon thin film 416. The sacrifice layer 414 is not silicided. Further, the mirror portion 416c of the structural body is protected by the oxide film 418 and hence, there is no concern that the mirror portion 416c is silicided (see FIG. 8B).

In the metal removing step S302-4, as illustrated in FIG. 8C, metal that is not silicided at the time of performing siliciding and remains on an upper surface of the silicide layer 122 is removed by etching.

### 4-3. Sacrifice Layer Removing Step

The sacrifice layer removing step S303 is a step where, with respect to the sacrifice layer 414, on the SOI substrate 410, the sacrifice layer 414 that exists at regions on both left and right ends is left and the sacrifice layer 314 at other places is removed (FIG. 8D). By performing such a step, the structure of the MEMS mirror 40 where the structure body including the mirror portion 416c, the beam portion 416d and the beam portion 416e is spaced apart from the silicon substrate 400 is completed. Further, in the sacrifice removing layer S303, the oxide film 418 formed on a surface of the mirror portion 416c is also removed.

### 4-4. Plating Layer Forming Step

The plating layer forming step S304 is a step where a plating layer 426 is formed by electroless plating (see FIG. 8C). As a material that can be used in plating, metal such as nickel, copper, gold, silver, zinc, tin, chromium or the like, or two or more metals selected from the above-mentioned metals can be exemplified.

In the plating layer forming step S304, the plating layer 426 is formed on the silicide layer 122 in a self-aligning manner. That is, in the plating layer forming step S304, a plating material selectively precipitates only on a surface of the silicide layer 422, and there is no possibility that a plating material precipitates on the surface of the support substrate 412 and the surface of the mirror portion 416c.

The manufacturing method of the MEMS mirror 40 and the surface treatment method of a silicon body in the MEMS mirror 40 according to the embodiment 4 described above include the silicide layer forming step S2 where silicide layer is formed by siliciding the surface of the silicon thin film 416. With such treatment, it is possible to precipitate plating on the surface of the silicon thin film that is made of a difficult-to-plate material. Further, by forming the plating layer 426 on the surface of the silicon thin film, it is possible to provide the manufacturing method of the MEMS mirror 40 and a surface treatment method of a silicon body that enhance a mechanical property, to be more specific, a torsional strength of the silicon body.

That is, the manufacturing method of the MEMS mirror 40 according to the embodiment 4, with respect to the beam portion 416d and the beam portion 416e, the silicide layer 422 is formed by siliciding the surface of the silicon body thus enhancing the precipitation of plating on the surface of the silicide layer 422. Accordingly, it is possible to provide the manufacturing method of the MEMS mirror 40 that can enhance a mechanical property of the silicon body.

On the other hand, the oxide film 418 is formed on the mirror portion 416c and hence, the silicide layer 422 is not formed. Since the silicide layer 422 is not formed, the plating layer 426 is not also formed. Accordingly, it is possible to acquire an advantageous effect that the smoothness of the mirror portion 416c can be maintained.

1. A surface treatment method for a silicon body of a silicon structural body comprising:
a silicide layer forming step of forming a silicide layer by siliciding a surface of the silicon body; and
a plating layer forming step of forming a plating layer on the silicide layer.

2. The surface treatment method for a silicon body of a silicon structural body according to claim 1, wherein
the plating layer forming step is a step of forming the plating layer on the silicide layer in a self-aligning manner.

3. The surface treatment method for a silicon body of a silicon structural body according to claim 1, wherein
the plating layer forming step is a step of forming the plating layer by electroless plating or electrolytic plating.

4. The surface treatment method for a silicon body of a silicon structural body according to claim 1, wherein
the plating layer forming step is a step of forming a plating layer that contains that contains one or more metals selected from nickel, copper, gold, silver, zinc, tin and chromium.

5. The surface treatment method for a silicon body of a silicon structural body according to claim 1, wherein
the silicide layer forming step includes: a step of forming a thin film that contains one or more materials from a silicon oxide and an inorganic compound that obstruct formation of the silicide layer for forming a region of a surface of the silicon body where the silicide layer is not formed; and a step of forming a metal layer in a region of a surface of the silicon body where the thin film is not formed.

6. The surface treatment method for a silicon body of a silicon structural body according to claim 1, wherein
the silicon body is a silicon thin film formed over a support substrate.

7. The surface treatment method for a silicon body of a silicon structural body according to claim 1, wherein
the silicon body is a single-crystal silicon body or a poly-crystal silicon body.

8. A manufacturing method of a silicon structural body comprising:
a silicide layer forming step of forming a silicide layer by siliciding a surface of a silicon body; and
a plating layer forming step of forming a plating layer on the silicide layer.
